(19) United States
(12) Patent Application Publication
(10) Pub. No.: US 2019/0146261 A1
(43) Pub. Date: May 16, 2019

(54) DISPLAY DEVICE AND METHOD OF MANUFACTURING THE SAME

(71) Applicant: Samsung Display Co., Ltd., Yongin-Si (KR)

(72) Inventors: Wan-soon IM, Cheonan-si (KR); Shoyeon KIM, Hwaseong-si (KR); Yongtae CHO, Yongin-si (KR); Byunghwan CHU, Seoul (KR)

(21) Appl. No.: 16/130,710

(22) Filed: Sep. 13, 2018

(30) Foreign Application Priority Data
Nov. 14, 2017 (KR) 10-2017-0151273

(51) Int. Cl. G02F 1/1333; H05K 1/02; H05K 1/18; G02F 1/1335

(52) U.S. Cl. CPC G02F 1/133305; G02F 1/133514; H05K 1/189; H05K 1/028

(57) ABSTRACT

A display device includes: a first substrate having a flat part and a bending part bent from the flat part; a second substrate facing the first substrate, and having a first part overlapping the flat part in a thickness direction of the first substrate to display a first image, and a second part that is spaced apart from the first part to expose a portion of the bending part, overlaps the bending part in the thickness direction, and displays a second image; and an adhesive layer disposed in a space between the first part and the second part spaced apart from each other to bond the first substrate and the second substrate.

### CROSS-REFERENCE TO RELATED APPLICATION

This U.S. non-provisional patent application claims priority under 35 U.S.C. § 119 to Korean Patent Application No. 10-2017-0151273, filed on Nov. 14, 2017, the entire contents of which are hereby incorporated by reference.

### BACKGROUND

The present inventive concept relates to a display device, and more particularly, to a display device and a method of manufacturing the same.

Various display devices are being developed that are used for multimedia devices such as a television, a mobile phone, a tablet computer, a navigation device, and a game machine. A display device includes a display panel for displaying an image, and the display panel includes a plurality of display elements for displaying an image. A display panel may be provided as an organic light-emitting display panel for emitting light itself, or as a liquid crystal display panel for receiving external light so as to display an image.

Meanwhile, in recent years, a variety of flexible display devices such as a foldable display device and a curved display device are under development.

### SUMMARY

The present disclosure provides a display device including a first display surface on which an image is viewed in a first direction, and a second display surface on which an image is viewed in a second direction crossing the first direction, and a method of manufacturing the same.

An embodiment of the inventive concept provides a display device including: a first substrate including a flat part and a bending part bent from the flat part; a second substrate facing the first substrate, and including a first part overlapping the flat part in a thickness direction of the first substrate and a second part that is spaced apart from the first part to expose a portion of the bending part and overlaps the bending part in the thickness direction; a display element layer disposed between the first substrate and the second substrate; and an adhesive layer disposed in a space between the first part and the second part spaced apart from each other, and configured to bond the first substrate and the second substrate.

In an embodiment, the display element layer may include: a first liquid crystal part disposed between the flat part and the first part; and a second liquid crystal part spaced apart from the first liquid crystal part and disposed between the bending part and the second part, the adhesive layer is disposed between the first liquid crystal part and the second liquid crystal part.

In an embodiment, the display device may further include a first sealing layer disposed between the flat part and the first part so as to seal the first liquid crystal part, and a second sealing layer disposed between the bending part and the second part so as to seal the second liquid crystal part.

In an embodiment, the display device may further include a first polarization layer disposed on the first substrate, and a second polarization layer configured to cover the adhesive layer and disposed on the second substrate.

In an embodiment, the display device may further include: a first color filter disposed on the first part; and a second color filter spaced apart from the first color filter and disposed on the second part, the adhesive layer is disposed between the first color filter and the second color filter.

In an embodiment, the bending part and the second part may be bent in a direction from the second substrate to the first substrate.

In an embodiment, the bending part and the second part may be bent in a direction from the first substrate to the second substrate.

In an embodiment, the bending part may include a first bending part and a second bending part respectively bent from one end and the other end of the flat part.

In an embodiment, the second part may include: a first sub-part spaced apart from one end of the first part, and configured to expose a portion of the first bending part and overlap the first bending part; and a second sub-part spaced apart from the other end of the first part, and configured to expose a portion of the second bending part and overlap the second bending part.

In an embodiment, the adhesive layer may include a first adhesive layer disposed between the first part and the first sub-part, and a second adhesive layer disposed between the first part and the second sub-part.

In an embodiment, the second part may be bent with a curvature equal to a curvature of the bending part.

In an embodiment, the second part may be flat.

In an embodiment, a first image displayed from the first part and a second image displayed from the second part may be respectively displayed in directions substantially perpendicular to each other.

In an embodiment, the second substrate may be provided as an encapsulation substrate.

In an embodiment, the display element layer may include: a first organic element part disposed between the flat part and the first part; and a second organic element part spaced apart from the first organic element part and disposed between the bending part and the second part, the adhesive layer is disposed between the first organic element part and the second organic element part.

In an embodiment, the display device may further include a polarization layer configured to cover the adhesive layer and disposed on the second substrate.

An embodiment of the inventive concept provides a method of manufacturing a display device, the method including: providing a first substrate including a flat part in which a plurality of first pixels are arranged, and a bending part which extends from the flat part and in which a plurality of second pixels are arranged; disposing, on the first substrate, a second substrate including a first part overlapping the flat part and a second part extending from the first part to overlap the bending part, in a thickness direction of the first substrate; removing a portion of the second part so that the second part is spaced apart from the first part; disposing an adhesive layer for bonding the first substrate and the second substrate in the removed portion; and bending the bending part and the second part.

In an embodiment, the bending part and the second part may be bent in a direction from the second substrate to the first substrate.

In an embodiment, the adhesive layer may be silicone.

In an embodiment, the first substrate and the second substrate may be flexible.

### BRIEF DESCRIPTION OF DRAWINGS

The accompanying drawings are included to provide a further understanding of the inventive concept, and are incorporated in and constitute a part of this specification. The drawings illustrate exemplary embodiments of the inventive concept and, together with the description, serve to describe principles of the inventive concept. In the drawings:

FIG. 1A is a perspective view illustrating a display device according to an embodiment of the inventive concept;

FIG. 1B is a perspective view illustrating a display device according to another embodiment of the inventive concept;

FIG. 1C is a perspective view illustrating a display device according to another embodiment of the inventive concept;

FIG. 2 is a plan view illustrating the display device according to an embodiment of the inventive concept;

FIG. 3 is a block diagram illustrating the display device according to an embodiment of the inventive concept;

FIG. 4A is an equivalent circuit diagram of a pixel illustrated in FIG. 3, according to an embodiment of the inventive concept;

FIG. 4B is a cross-sectional view taken along line I-I′ of FIG. 2, according to an embodiment of the inventive concept;

FIG. 5A is an equivalent circuit diagram of a pixel illustrated in FIG. 3, according to another embodiment of the inventive concept;

FIG. 5B is a cross-sectional view taken along line I-I′ of FIG. 2, according to another embodiment of the inventive concept;

FIG. 6A is an enlarged view of area AA illustrated in FIG. 2, according to an embodiment of the inventive concept;

FIG. 6B is an enlarged view of the area AA illustrated in FIG. 2, according to another embodiment of the inventive concept; and

FIGS. 7A to 7D illustrate a method of manufacturing a display device according to an embodiment of the inventive concept.

### DETAILED DESCRIPTION

As the inventive concept can have various changes and modifications made thereto and take many forms, specific embodiments of the inventive concept are illustrated in the accompanying drawings and are hereinafter described in detail. However, it should be understood that this is not intended to limit the inventive concept to specific disclosures, but is intended to include all changes and modifications, equivalents, and substitutes within the spirit and scope of the inventive concept.

Like reference numerals refer to like elements when the figures are described throughout this specification. Also, in the figures, the dimensions of components are exaggerated for effective description of the technical content. It will be understood that, although the terms first, second, etc. may be used herein to describe various elements, components, and/or sections, these elements, components, and/or sections should not be limited by these terms. These terms are used only to distinguish one element, component, or section from another element, component, or section. Thus, a first element, component, or section discussed below could be termed a second element, component, or section without departing from the teachings of the inventive concept. As used herein, the singular forms, “a”, “an” and “the” are intended to include the plural forms as well, unless the context clearly indicates otherwise.

It will be further understood that the terms “comprise” and/or “include”, when used in this specification, specify the presence of a stated feature, number, step, operation, element, component, or a combination thereof, but do not exclude the presence or addition of one or more other features, numbers, steps, operations, elements, components, or combinations thereof.

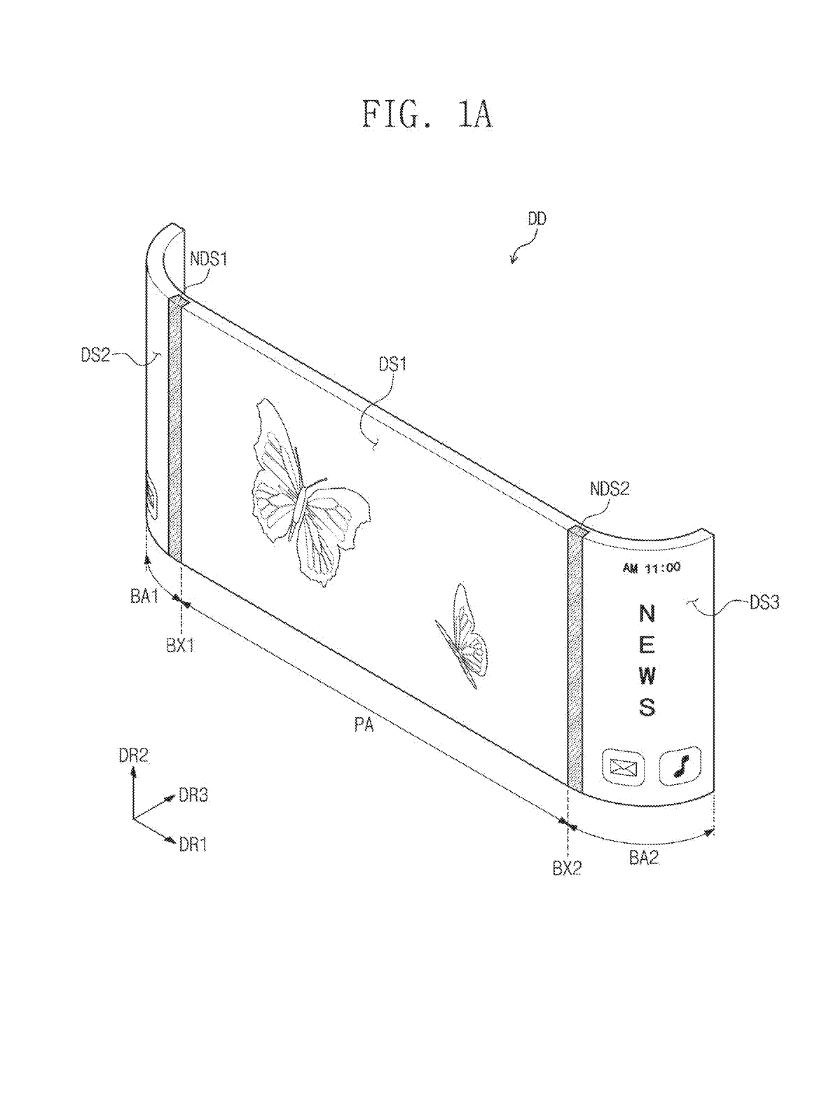

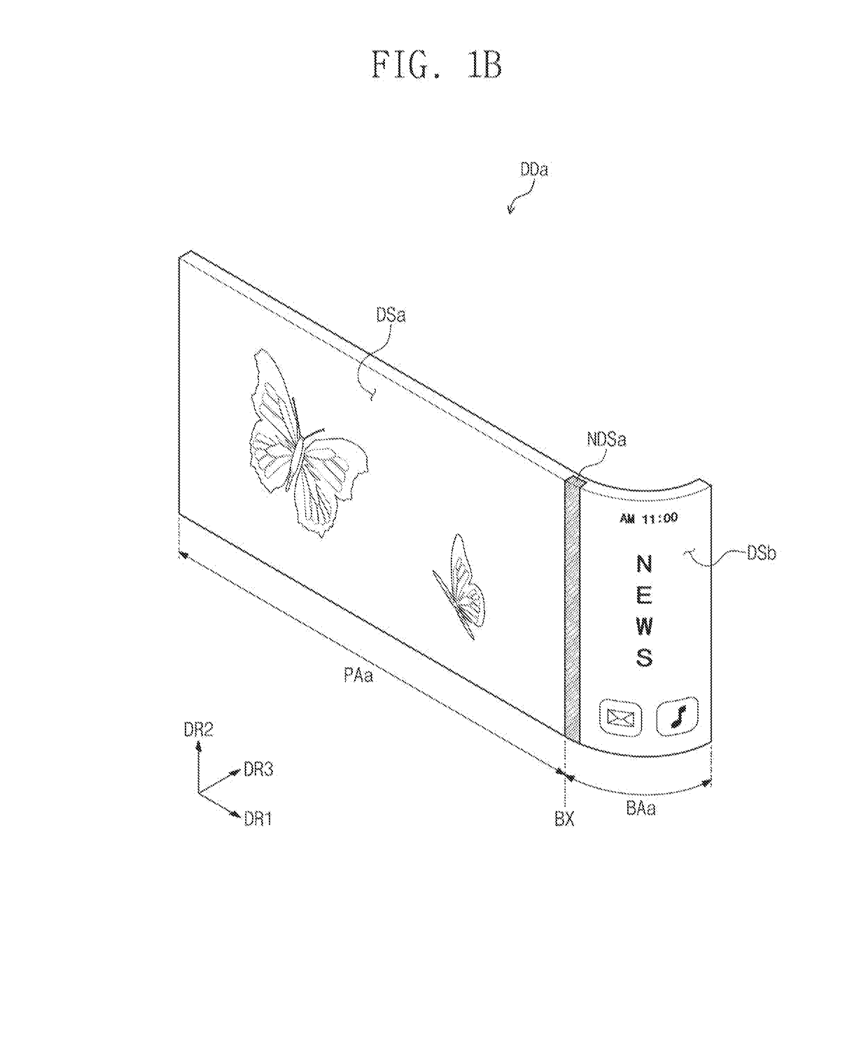

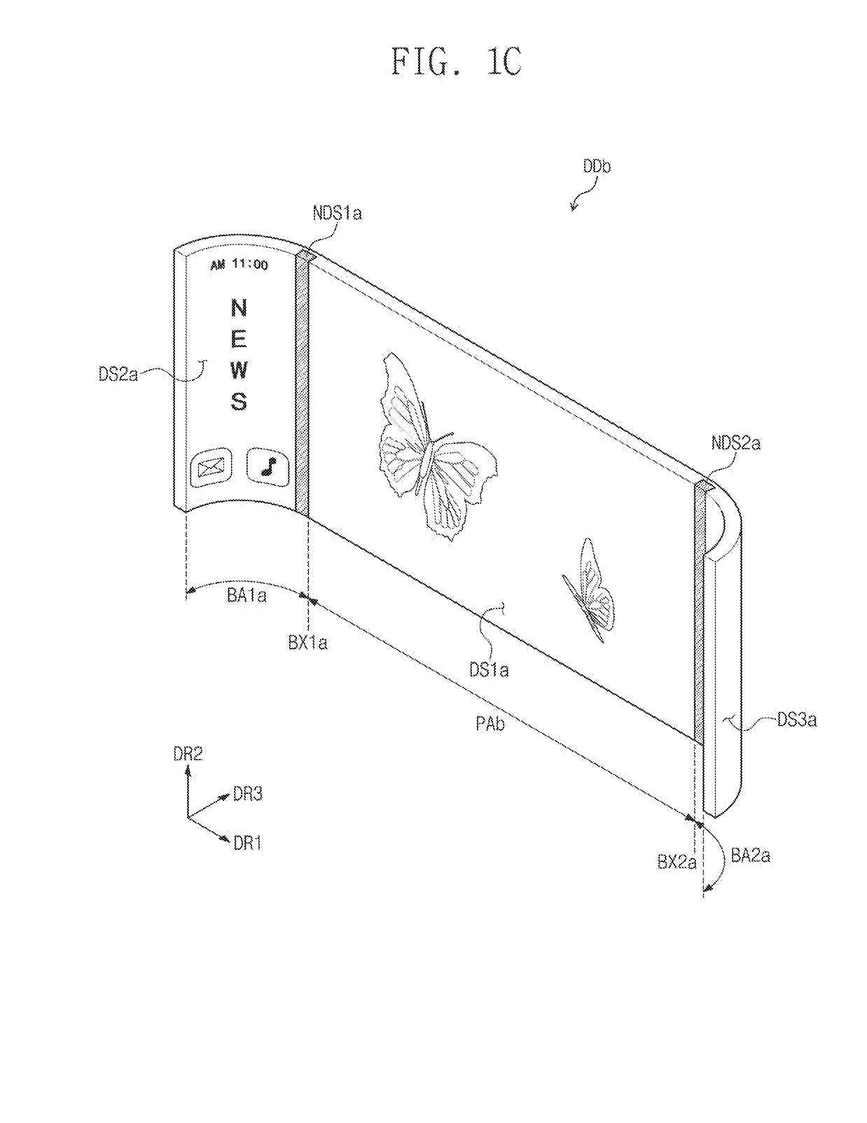

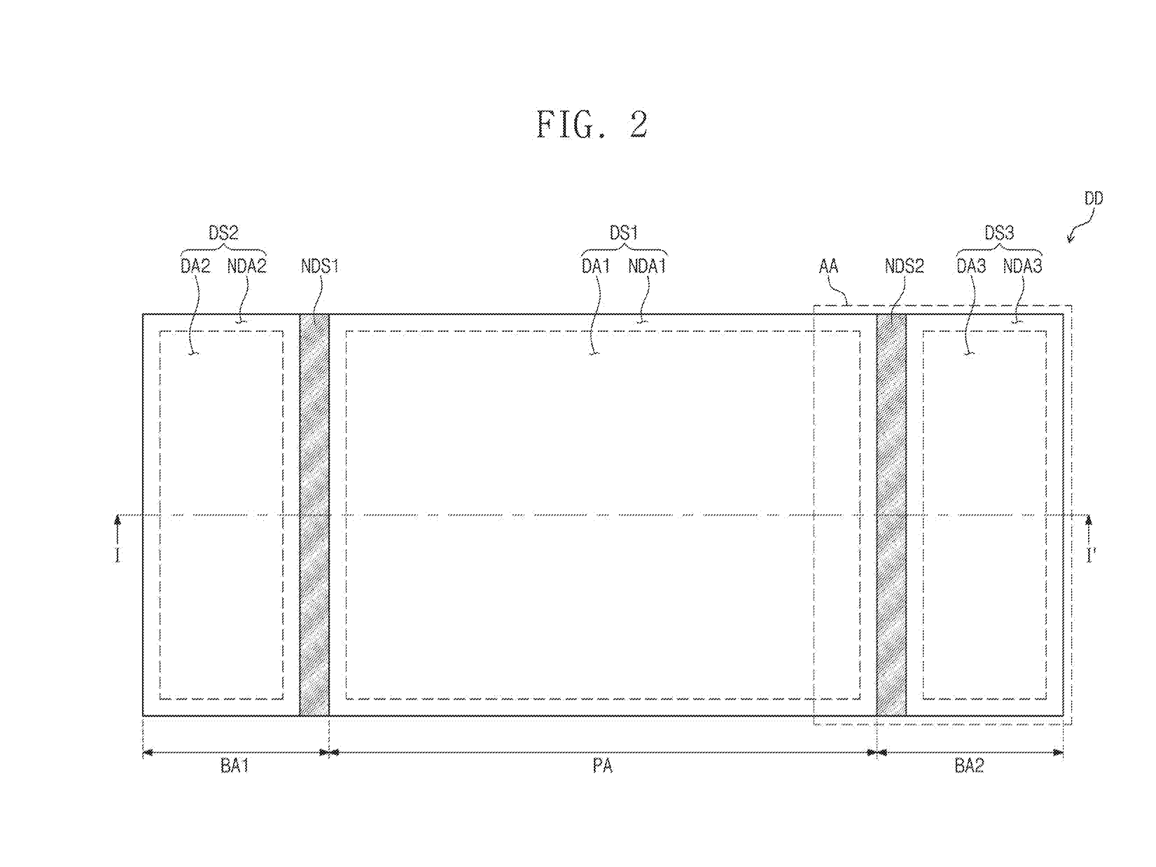

FIG. 1A is a perspective view illustrating a display device according to an embodiment of the inventive concept. FIG. 1B is a perspective view illustrating a display device according to another embodiment of the inventive concept. FIG. 1C is a perspective view illustrating a display device according to another embodiment of the inventive concept. FIG. 2 is a plan view illustrating the display device according to an embodiment of the inventive concept.

A display device DD that may be applied to a large-sized television is illustrated as an embodiment of the inventive concept. However, the display device DD according to an embodiment of the inventive concept is not limited thereto, and may be applied to electronic devices such as a television, a smartphone, a personal computer, a laptop computer, a vehicle navigation device, a game machine, an acoustic electronic device, a smart watch, and a camera. These are merely exemplary embodiments, and the display device DD may also be employed, of course, in other electronic devices as long as the other electronic devices do not deviate from the inventive concept.

Referring to FIGS. 1A and 2, the display device DD includes a flat area PA, and a first bending area BA1 and a second bending area BA2 bent from an end of the flat area PA.

The flat area PA includes a first display surface DS1 for displaying a first image. As illustrated in FIG. 2, the first display surface DS1 may include a first display area DA1 for displaying the first image, and a first non-display area NDA1 surrounding the first display area DA1.

Here, the first display surface DS1 for displaying the first image is parallel with a surface defined by a first direction DR1 and a second direction DR2. A normal direction of the first display surface DS1, i.e. a thickness direction of the display device DD is indicated by a third direction DR3. A front surface (or an upper surface) and a rear surface (or a lower surface) of each member are distinguished by the third direction DR3. However, the directions indicated by the first to third directions DR1 to DR3 are a relative concept, and may be converted into other directions. Hereinafter, first to third directions are the directions indicated by the first to third directions DR1 to DR3 respectively, and the same reference numerals are referred to.

The first bending area BA1 may be bent from one end of the flat area PA with respect to a first bending axis BX1, and the second bending area BA2 may be bent from the other end of the flat area PA with respect to a second bending axis BX2. That is, the first bending area BA1 and the second bending area BA2 may face each other with the flat area PA therebetween.

According to an embodiment, the first bending area BA1 and the second bending area BA2 may be bent in a direction from a front surface to a rear surface of the display device DD. Here, the front surface of the display device DD may be a display surface on which an image is displayed, and the rear surface may be a surface facing the front surface.

The first bending area BA1 may include a second display surface DS2 for displaying a second image and a first non-display surface NDS1, and be provided in a planar shape or a curved shape. As illustrated in FIG. 2, the second display surface DS2 includes a second display area DA2 for displaying the second image, and a second non-display area NDA2 surrounding the second display area DA2. The first non-display surface NDS1 may be disposed between the first display area DA1 and the second display area DA2 in the first direction DR1.

The second bending area BA2 may include a third display surface DS3 for displaying a third image and a second non-display surface NDS2, and be provided in a planar shape or a curved shape. As illustrated in FIG. 2, the third display surface DS3 includes a third display area DA3 for displaying the third image, and a third non-display area NDA3 surrounding the third display area DA3. The second non-display surface NDS2 may be disposed between the first display area DA1 and the third display area DA3 in the first direction DR1.

As an example, the first to third display surfaces DS1 to DS3 may respectively display the same images, or images different from each other. As an example, the second display surface DS2 and the third display surface DS3 may respectively display the same images, and the first display surface DS1 may display a different image. Here, the second and third display surfaces DS2 and DS3 may provide images such as news information, weather information, and time information. In particular, each of the second and third display surfaces DS2 and DS3 may independently display images of a variety of information.

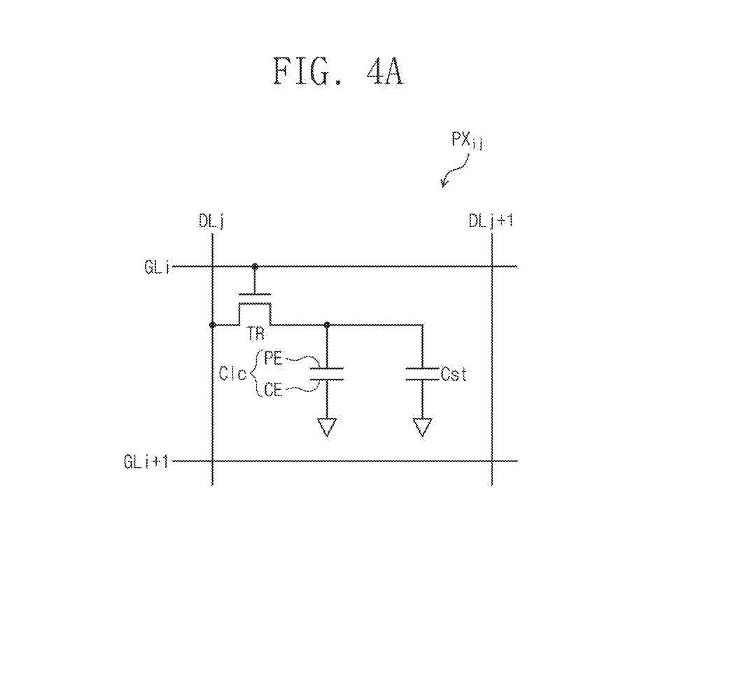

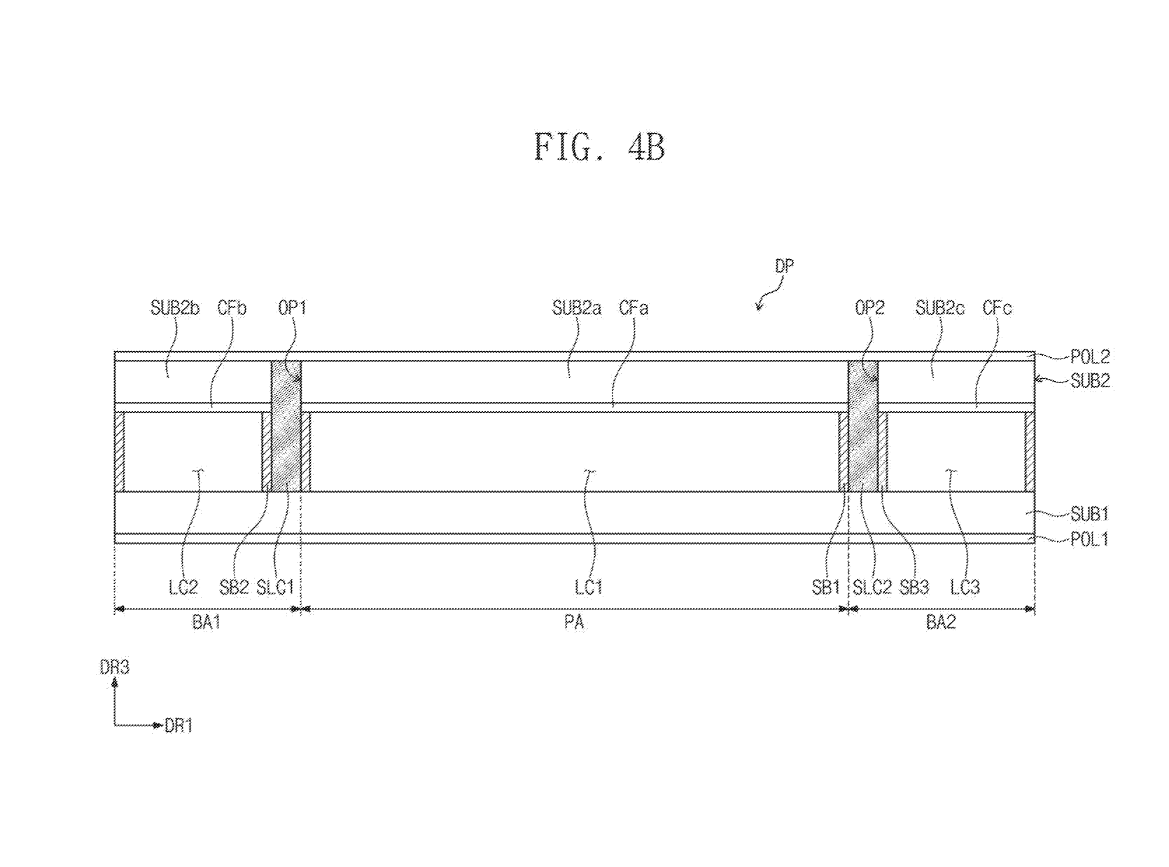

The first non-display surface NDS1 may be disposed between the first display surface DS1 and the second display surface DS2. The second non-display surface NDS2 may be disposed between the first display surface DS1 and the third display surface DS3. In particular, the first and second bending areas BA1 and BA2 may be easily bent from the flat area PA due to the first and second non-display surfaces NDS1 and NDS2 respectively. Detailed description about this will be given with reference to FIGS. 2 and 4B.

Referring to FIG. 1B, a display device DDa includes a flat area PAa and a bending area BAa bent from the flat area PAa. The bending area BAa may be bent from one end of the flat area PAa with respect to a bending axis BX. The flat area PAa includes a first display surface DSa, and the bending area BAa includes a second display surface DSb and a non-display surface NDSa disposed between the first display surface DSa and the second display surface DSb.

The display device DDa illustrated in FIG. 1B may include a single bending area BAa when compared with the display device DD illustrated in FIG. 1A. Here, the flat area PAa may correspond to the flat area PA of FIG. 1A, and the bending area BAa may correspond to any one of the first bending area BA1 and the second bending area BA2 of FIG. 1A.

Referring to FIG. 1C, a display device DDb includes a flat area PAb, and first and second bending areas BA1a and BA2a bent from the flat area PAb.

The flat area PAb includes a first display surface DS1a for displaying a first image. The first bending area BA1a may be bent from one end of the flat area PAb with respect to a first bending axis BX1a, and the second bending area BA2a may be bent from the other end of the flat area PAb with respect to a second bending axis BX2a. That is, the first bending area BA1a and the second bending area BA2a may face each other with the flat area PAb disposed therebetween.

According to an embodiment, the first bending area BA1a and the second bending area BA2a may be bent in a direction from a rear surface to a front surface of the display device DDb. The first bending area BA1a includes a second display surface DS2a for displaying a second image and a first non-display surface NDS1a. The second bending area BA2a includes a third display surface DS3a for displaying a third image and a second non-display surface NDS2a.

As described in detail in FIG. 1A above, the first and second bending areas BA1a and BA2a may be easily bent from the flat area PAb due to the first and second non-display surfaces NDS1a and NDS2a respectively. Detailed description about this will be given with reference to FIGS. 2 and 4B.

As an example, the first to third display surfaces DS1a to DS3a may respectively display the same images, or images different from each other. As another example, the first to third display surfaces DS1a to DS3a may display a single image.

According to an embodiment, the first bending area BA1 and the second bending area BA2 may be bent in a direction from the front surface to the rear surface of the display device DD. Here, the front surface of the display device DD may be a display surface on which an image is displayed, and the rear surface may be a surface facing the front surface.

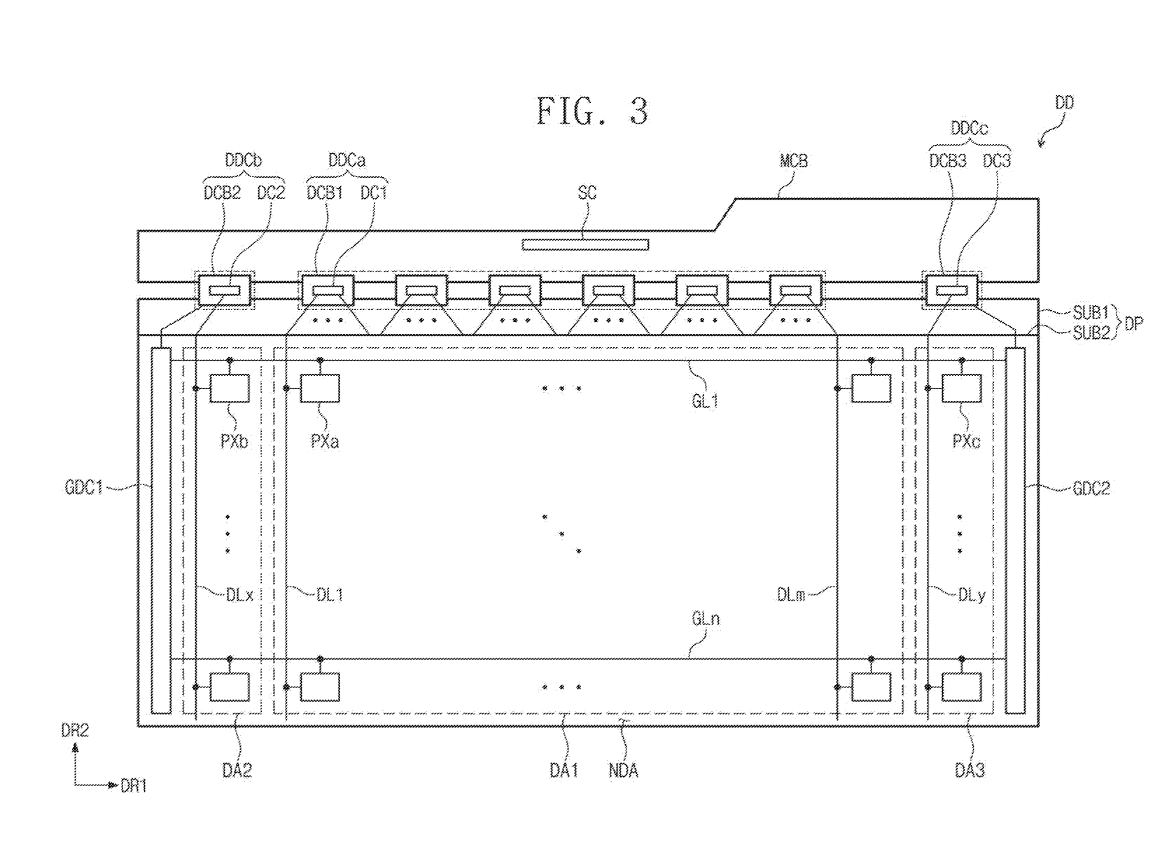

FIG. 3 is a block diagram illustrating the display device according to an embodiment of the inventive concept. FIG. 4A is an equivalent circuit diagram of a pixel illustrated in FIG. 3, according to an embodiment of the inventive concept. FIG. 4B is a cross-sectional view taken along line I-I′ of FIG. 2, according to an embodiment of the inventive concept.

Referring to FIG. 3, the display device DD includes a first gate driving circuit GDC1, a second gate driving circuit GDC2, first to third data driving circuits DDCa, DDCb and DDCc, a circuit board MCB, and a display panel DP.

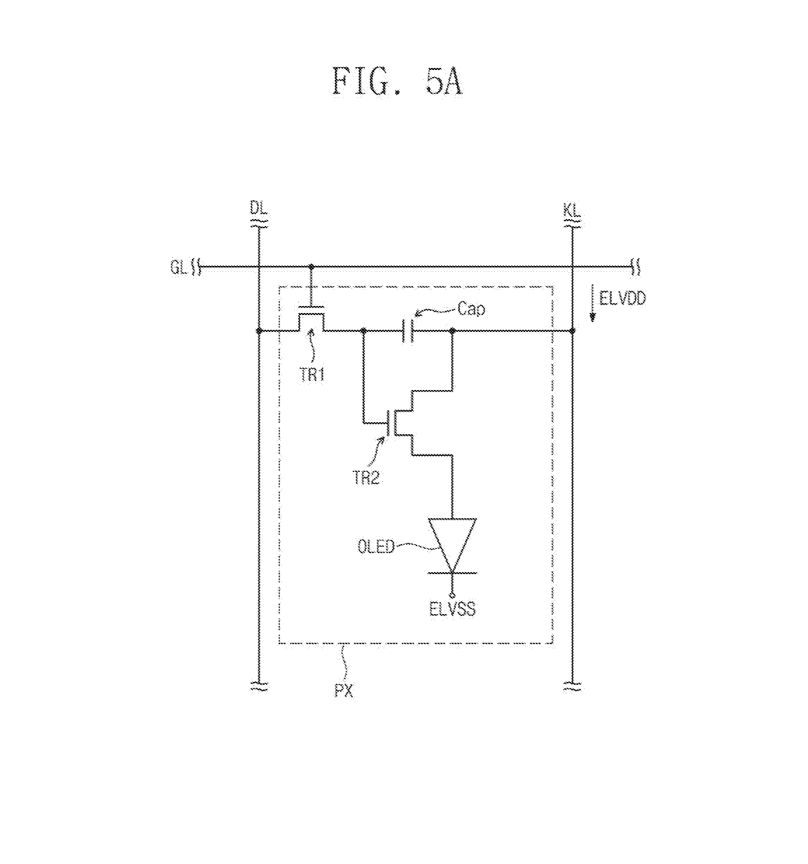

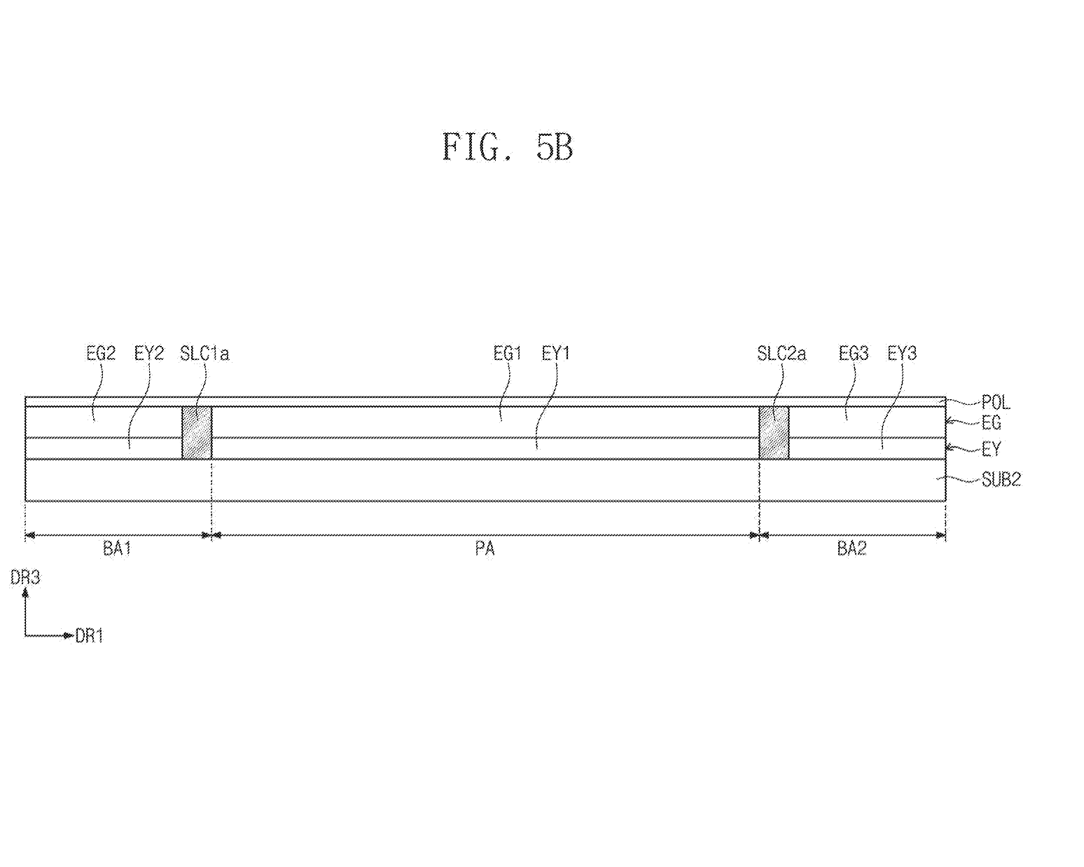

According to an embodiment of the inventive concept, the display panel DP may be a liquid crystal display panel, an organic light-emitting display panel, an electrophoretic display panel, an electrowetting display panel or the like, and the type thereof is not limited. Hereinafter, a liquid crystal display panel is described by way of example according to FIGS. 4A and 4B, and an organic light-emitting display panel is described by way of example according to FIGS. 5A and 5B.

The display panel DP includes the first display area DA1 in which a plurality of first pixels PXa are arranged, the second display area DA2 in which a plurality of second pixels PXb are arranged, and the third display area DA3 in which a plurality of third pixels PXc are arranged, as described with reference to FIG. 2. A non-display area NDA may surround the first to third display areas DA1 to DA3.

In particular, the non-display area NDA may include the first non-display area NDA1 surrounding the first display area DA1, the second non-display area NDA2 surrounding the second display area DA2, and the third non-display area NDA3 surrounding the third display area DA3, as described with reference to FIG. 2.

According to an embodiment of the inventive concept, the first non-display area NDA1 and the second non-display area NDA2 may be separated by the first non-display surface NDS1 illustrated in FIG. 2. The first non-display area NDA1 and the third non-display area NDA3 may be separated by the second non-display surface NDS2 illustrated in FIG. 2. In other words, the first non-display surface NDS1 is disposed between the first non-display area NDA1 and the second non-display area NDA2, and the second non-display surface NDS2 is disposed between the first non-display area NDA1 and the third non-display area NDA3.

The display panel DP may include a first substrate SUB1 and a second substrate SUB2 disposed on the first substrate SUB1.

A plurality of gate lines GL1 to GLn, and a plurality of data lines crossing the gate lines GL1 to GLn are arranged on the first substrate SUB1. The plurality of gate lines GL1 to GLn extend along the first direction DR1, are formed of the same material and are formed in one piece on the flat area PA, the first bending area BA1 and the second bending area BA2. The data lines include first data lines DL1 to DLm connected to the first pixels PXa of the first display area DA1, a second data line DLx connected to the second pixels PXb of the second display area DA2, and a third data line DLy connected to the third pixels PXc of the third display area DA3. Illustrated in FIG. 3 are only some of the plurality of gate lines GL1 to GLn and a plurality of the first data lines DL1 to DLm.

Meanwhile, according to description of the inventive concept, the second pixels PXb are connected to the single second data line DLx, and the third pixels PXc are connected to the single third data line DLy, but the same are not limited thereto. In other words, the second data line DLx may be provided in plurality, and the second pixels PXb may be respectively connected to the plurality of second data lines DLx. Additionally, the third data line DLy may be provided in plurality, and the third pixels PXc may be respectively connected to the plurality of third data lines DLy.

The first data lines DL1 to DLm are connected to the first data driving circuit DDCa so as to receive data signals (or data voltages) in an analog form. Each of the first pixels PXa is connected to a corresponding gate line of the gate lines GL1 to GLn and a corresponding data line of the first data lines DL1 to DLm.

The second data lines DLx are connected to the second data driving circuit DDCb so as to receive data signals (or data voltages) in an analog form. Each of the second pixels PXb is connected to a corresponding gate line of the gate lines GL1 to GLn and the second data line DLx.

The third data lines DLy are connected to the third data driving circuit DDCc so as to receive data signals (or data voltages) in an analog form. Each of the third pixels PXc is connected to a corresponding gate line of the gate lines GL1 to GLn and the third data line DLy.

The first to third data driving circuits DDCa to DDCc receive data signals from a signal controller SC mounted on the circuit board MCB, and generate the analog data signals corresponding to the data signals.

In particular, by way of example, the signal controller SC may perform control so that the first to third display areas DA1 to DA3 respectively display the same images, or images different from each other.

The first data driving circuit DDCa includes a first driving chip DC1 and a first flexible circuit board DCB1 on which the first driving chip DC1 is mounted. Each of the first driving chip DC1 and the first flexible circuit board DCB1 may be provided in plurality. The first flexible circuit board DCB1 electrically connects the circuit board MCB and the first substrate SUB1. The plurality of first driving chips DC1 respectively provide data signals to corresponding data lines.

The second data driving circuit DDCb includes a second driving chip DC2 and a second flexible circuit board DCB2 on which the second driving chip DC2 is mounted. The second flexible circuit board DCB2 electrically connects the circuit board MCB and the first substrate SUB1. The second driving chip DC2 provides a data signal to the second data line DLx.

The third data driving circuit DDCc includes a third driving chip DC3 and a third flexible circuit board DCB3 on which the third driving chip DC3 is mounted. The third flexible circuit board DCB3 electrically connects the circuit board MCB and the first substrate SUB1. The third driving chip DC3 provides a data signal to the third data line DLy.

The first and second gate driving circuits GDC1 and GDC2 may be formed simultaneously with the pixels PXa, PXb and PXc through a thin film process. For example, the first and second gate driving circuits GDC1 and GDC2 may be respectively integrated in the second and third non-display areas NDA2 and NDA3 through an oxide semiconductor gate driver circuit (OSG) process or an amorphous silicon gate driver circuit (ASG) process.

One ends of the gate lines GL1 to GLn may be connected to the first gate driving circuit GDC1, and the other ends of the gate lines GL1 to GLn may be connected to the second gate driving circuit GDC2. The gate lines GL1 to GLn sequentially receive gate signals from the first gate driving circuit GDC1 and the second gate driving circuit GDC2.

As another example, each of the gate lines GL1 to GLn may be connected to the first gate driving circuit GDC1 and the second gate driving circuit GDC2, respectively. For example, the first gate line GL1 may include a first sub-gate line connected to the first gate driving circuit GDC1, and a second sub-gate line connected to the second gate driving circuit GDC2.

Meanwhile, each of the pixels arranged in the first to third display areas DA1 to DA3 may have an equivalent circuit illustrated in FIG. 4A.

As illustrated in FIG. 4A, a pixel PXij includes a thin film transistor TR, a liquid crystal capacitor Clc, and a storage capacitor Cst. By way of example, the thin film transistor TR electrically connected to an ith gate line GLi and a jth data line DLj is disclosed. The thin film transistor TR outputs a data signal received from the jth data line DLj, in response to a gate signal received from the ith gate line GLi.

The liquid crystal capacitor Clc includes a pixel electrode PE and a common electrode CE. The pixel electrode PE is electrically connected to the thin film transistor TR, and receives a data voltage corresponding to the data signal outputted from the jth data line DLj. The common electrode CE receives a common voltage. Alignment of liquid crystal is altered according to a voltage difference between the pixel electrode PE and the common voltage. The storage capacitor Cst and the liquid crystal capacitor Clc are connected in parallel. The storage capacitor Cst maintains alignment of liquid crystal molecules for a certain period.

Referring to FIG. 4B, the display panel DP may be provided as a liquid crystal display panel. The display panel DP includes the first substrate SUB1, the second substrate SUB2, a first polarization layer POL1, a second polarization layer POL2, a color filter layer, and a display element layer.

First, the first substrate SUB1 may be a polymer substrate, a plastic substrate, a glass substrate, a quartz substrate or the like. The second substrate SUB2 may be a transparent insulating substrate. The second substrate SUB2 may be rigid or flexible.

According to an embodiment of the inventive concept, the first substrate SUB1 may include a flat part overlapping the flat area PA, a first bending part that is bent from one end of the flat part and overlaps the first bending area BA1, and a second bending part that is bent from the other end of the flat part and overlaps the second bending area BA2. That is, the flat part, the first bending part and the second bending part may respectively overlap the first display surface DS1, the second display surface DS2 and the third display surface DS3 illustrated in FIG. 2. The first substrate SUB1 which includes the flat area PA, the first bending part BA1 and the second bending part BA2 may be formed in one piece.

In addition, even though not illustrated, a circuit layer having the pixels included in the first to third display areas DA1 to DA3 may be disposed on the first substrate SUB1.

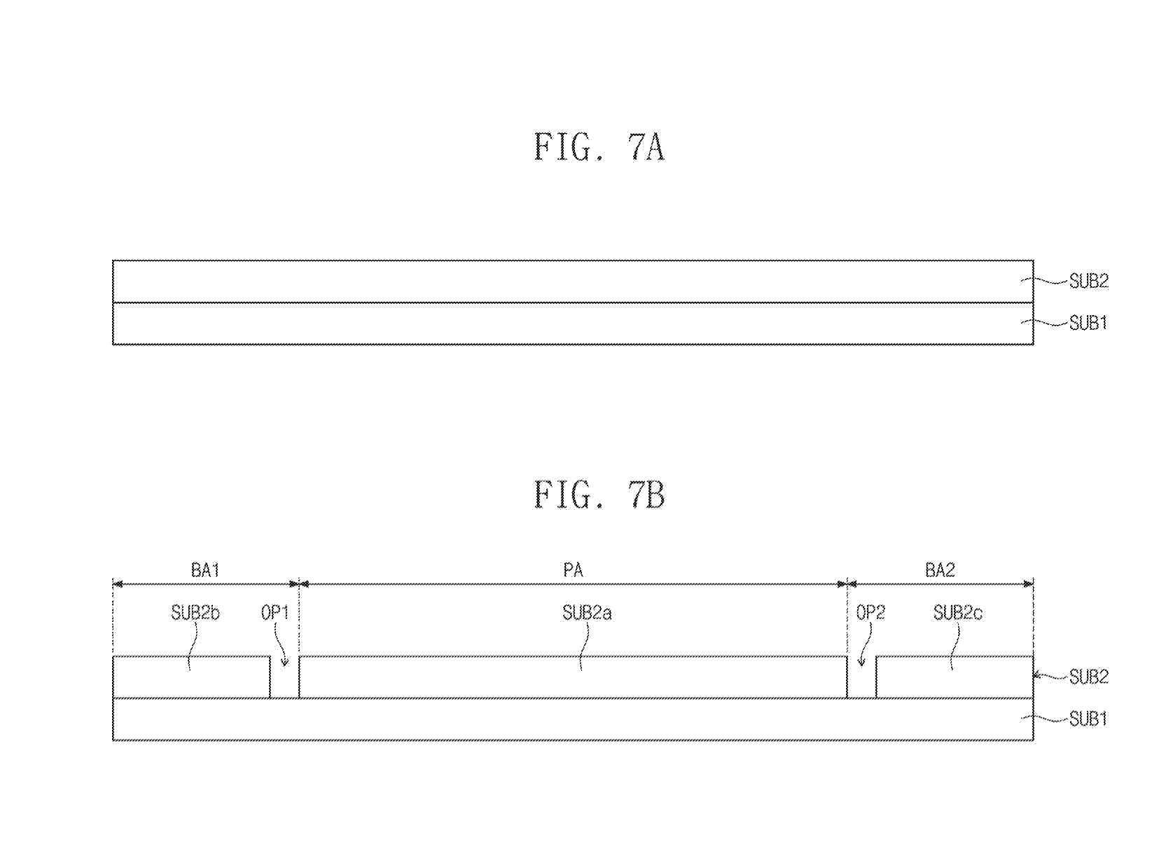

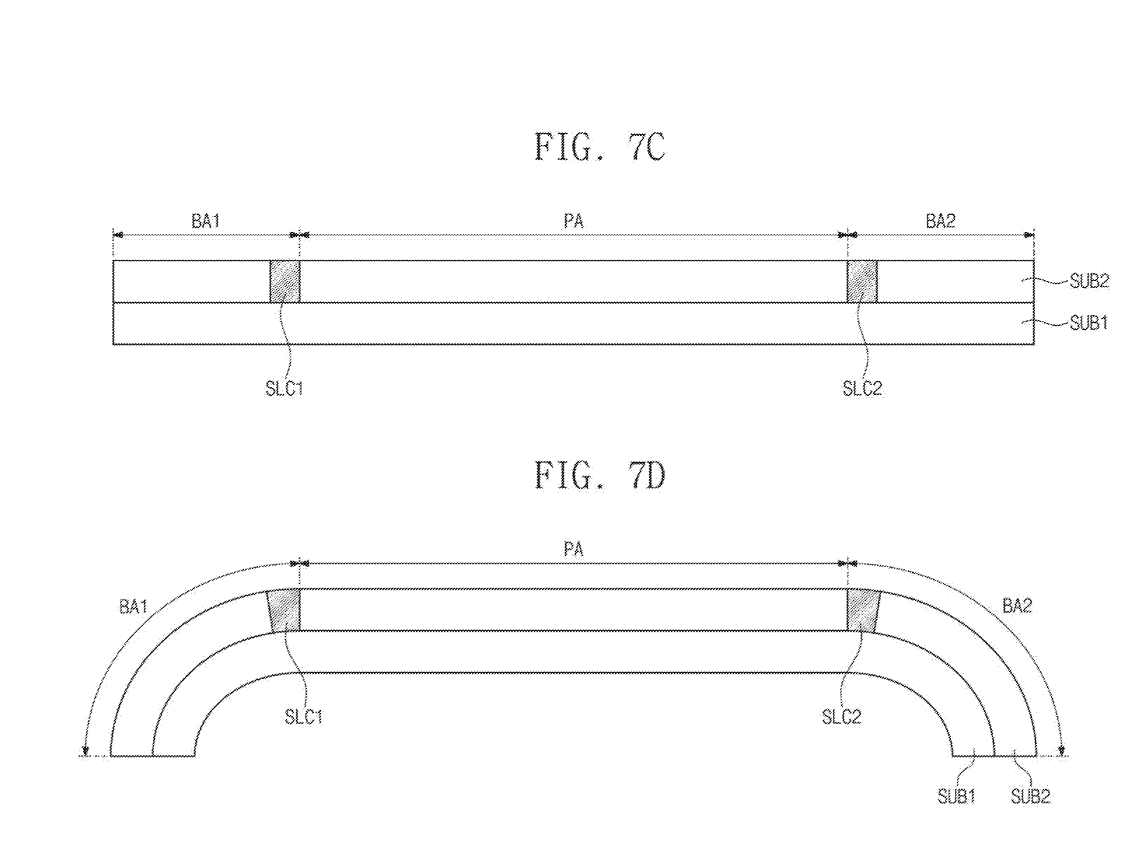

Meanwhile, according to FIG. 4B, the first bending area BA1 and the second bending area BA2 are illustrated to have shapes not bent from the flat area PA for description between components. However, the first bending area BA1 and the second bending area BA2 may be bent from the flat area PA as illustrated in FIGS. 1A to 1C. This is described in detail in FIG. 7D.

The second substrate SUB2 may face the first substrate SUB1 in the third direction DR3 and may be disposed on the first substrate SUB1. The second substrate SUB2 may be a polymer substrate, a plastic substrate, a glass substrate, a quartz substrate or the like. The second substrate SUB2 may be a transparent insulating substrate. The second substrate SUB2 may be rigid or flexible.

According to an embodiment, the second substrate SUB2 may include a first part SUB2a, a second part SUB2b, and a third part SUB2c which are separated from one another.

The first part SUB2a may overlap the flat part of the first substrate SUB1 in the third direction DR3, and display a first image. The second part SUB2b may overlap the first bending part of the first substrate SUB1 in the third direction DR3, and display a second image. The third part SUB2c may overlap the second bending part of the first substrate SUB1 in the third direction DR3, and display a third image.

According to an embodiment of the inventive concept, the first part SUB2a, the second part SUB2b, and the third part SUB2c may be spaced apart from each other. The second part SUB2b may be spaced apart from the first part SUB2a in the first direction DR1, and expose a portion of the first bending part of the first substrate SUB1. Accordingly, a first space OP1 may be defined as a space between the second part SUB2b and the first part SUB2a spaced apart from each other.

A first adhesive member SLC1 may be filled in the first space OP1 and bond the first substrate SUB1 and the second substrate SUB2. Specifically, the first adhesive layer SLC1 may be disposed between a front surface of the first substrate SUB1, the first part SUB2a, and the second part SUB2b. As a result, the first part SUB2a and the second part SUB2b may be separated by the first adhesive layer SLC1. By way of example, the first adhesive layer SLC1 may include silicone.

In addition, the third part SUB2c may be spaced apart from the first part SUB2a in the first direction DR1, and expose a portion of the second bending part of the first substrate SUB1. Accordingly, a second space OP2 may be defined as a space between the third part SUB2c and the first part SUB2a spaced apart from each other.

A second adhesive layer SLC2 may be filled in the second space OP2 and bond the first substrate SUB1 and the second substrate SUB2. Specifically, the second adhesive layer SLC2 may be disposed between the front surface of the first substrate SUB1, the first part SUB2a, and the third part SUB2c. As a result, the first part SUB2a and the third part SUB2c may be separated by the second adhesive layer SLC2. By way of example, the second adhesive layer SLC2 may include silicone.

The color filter layer may be disposed on the second substrate SUB2. According to an embodiment, the color filter layer may include first to third color filters CFa, CFb, and CFc. The first color filter CFa may overlap the flat area PA and be disposed on the first part SUB2a.

The second color filter CFb may be spaced apart from the first color filter CFa in the first direction DR1, partly overlap the first bending area BA1, and be disposed on the second part SUB2b. The first color filter CFa and the second color filter CFb may be separated by the first adhesive layer SLC1.

The third color filter CFc may be spaced apart from the first color filter CFa in the first direction DR1, partly overlap the second bending area BA2, and be disposed on the third part SUB2c. The first color filter CFa and the third color filter CFc may be separated by the second adhesive layer SLC2.

The display element layer may be disposed between the first substrate SUB1 and the second substrate SUB2. According to an embodiment, the display element layer may be provided as a liquid crystal layer, and include first to third liquid crystal parts LC1, LC2 and LC3.

The first liquid crystal part LC1 may be disposed between the flat part and the first part SUB2a. A first sealing layer SB1 may be disposed between the flat part and the first part SUB2a along an edge of the flat area PA. The first liquid crystal part LC1 may be sealed by the first sealing layer SB1.

The second liquid crystal part LC2 may be disposed between the first bending part and the second part SUB2b. A second sealing layer SB2 may be disposed between the first bending part and the second part SUB2b along an edge of the first bending area BA1. The second liquid crystal part LC2 may be sealed by the second sealing layer SB2.

According to an embodiment, the first sealing layer SB1 and the second sealing layer SB2 may be separated by the first adhesive layer SLC1 disposed in the first space OP1. In other words, the first sealing layer SB1, the first adhesive layer SLC1 and the second sealing layer SB2 are disposed between the first liquid crystal part LC1 and the second liquid crystal part LC2 Accordingly, the first space OP1 may be defined as a space between the first part SUB2a and the second part SUB2b spaced apart from each other, and a space between the first sealing layer SB1 and the second sealing layer SB2 spaced apart from each other.

The third liquid crystal part LC3 may be disposed between the second bending part and the third part SUB2c. A third sealing layer SB3 may be disposed between the second bending part and the third part SUB2c along an edge of the second bending area BA2. The third liquid crystal part LC3 may be sealed by the third sealing layer SB3.

According to an embodiment, the first sealing layer SB1 and the third sealing layer SB3 may be separated by the second adhesive layer SLC2 disposed in the second space OP2. In other words, the first sealing layer SB21, the second adhesive layer SLC2 and the third sealing layer SB32 are disposed between the first liquid crystal part LC1 and the third liquid crystal part LC3. Accordingly, the second space OP2 may be defined as a space between the first part SUB2a and the third part SUB2c spaced apart from each other, and a space between the first sealing layer SB1 and the third sealing layer SB3 spaced apart from each other.

The first polarization layer POL1 may be disposed on a rear surface of the first substrate SUB1. The first polarization layer POL1 transmits light provided from the outside parallel to a first polarization axis.

The second polarization layer POL2 may cover the first adhesive layer SLC1 and the second adhesive layer SLC2, and may be disposed on the second substrate SUB2. The second polarization layer POL2 may transmit incident light parallel to a second polarization axis perpendicular the first polarization axis.

According to detailed description above, the first adhesive layer SLC1 is disposed between the first bending area BA1 and the flat area PA, and the second adhesive layer SLC2 is disposed between the second bending area BA2 and the flat area PA. In particular, as the first adhesive layer SLC1 and the second adhesive layer SLC2 include a flexible material such as silicone, a better bending characteristic may result as compared with that of a second substrate SUB2 of a glass or plastic material.

In addition, the first bending area BA1 and the second bending area BA2 may be bent from the flat area PA with a better bending characteristic as compared with a case of a glass or plastic material as the first adhesive layer SLC1 and the second adhesive layer SLC2 are respectively disposed in the first space OP1 and the second space OP2.

FIG. 5A is an equivalent circuit diagram of a pixel illustrated in FIG. 3, according to another embodiment of the inventive concept. FIG. 5B is a cross-sectional view taken along line I-I′ of FIG. 2, according to another embodiment of the inventive concept.

Referring to FIG. 5A, a display panel DPa may be provided as an organic light-emitting display panel. Illustrated are any one gate line GL, any one data line DL, a power line KL, and a pixel PX connected thereto. A configuration of the pixel PX is not limited to that of FIG. 5A, and may be modified and implemented. Here, the pixel PX illustrated in FIG. 5A may be applied to each of the pixels, illustrated in FIG. 3, arranged in the first to third display areas DA1 to DA3.

An organic light-emitting diode OLED may be a top-emitting organic light-emitting diode or a bottom-emitting organic light-emitting diode. The pixel PX is a pixel driving circuit for driving the organic light-emitting diode OLED, and includes a first transistor TR1 (or a switching transistor), a second transistor TR2 (or a driving transistor), and a capacitor Cap. A first power voltage ELVDD is provided to the second transistor TR2, and a second power voltage ELVSS is provided to the organic light-emitting diode OLED. The second power voltage ELVSS may be lower than the first power voltage ELVDD.

The first transistor TR1 outputs a data signal applied to the data line DL in response to a scanning signal applied to the gate line GL. The capacitor Cap is charged to a voltage corresponding to the data signal received from the first transistor TR1. The second transistor TR2 is connected to the organic light-emitting diode OLED. The second transistor TR2 controls a driving current flowing in the organic light-emitting diode OLED in response to a quantity of electric charge stored in the capacitor Cap.

The equivalent circuit is only an embodiment, and the pixel PX is not limited thereto. The pixel PX may further include a plurality of transistors, and include more capacitors. The organic light-emitting diode OLED may also be connected between the power line KL and the second transistor TR2.

Referring to FIG. 5B, the display panel DPa includes a substrate SUB2, a display element layer EY, an encapsulation layer EG, and a polarization layer POL.

The substrate SUB2 may be a polymer substrate, a plastic substrate, a glass substrate, a quartz substrate, or the like. The substrate SUB2 may be a transparent insulating substrate. The substrate SUB2 may be rigid or flexible.

The display element layer EY may be disposed on the substrate SUB2. The display element layer EY may be provided as an organic element layer, and may include a plurality of pixels having an organic light-emitting diode and transistors as illustrated in FIG. 5A.

A plurality of organic light-emitting diodes as illustrated in FIG. 5A may be arranged in the display element layer EY. The display element layer EY may include first to third organic element parts EY1 to EY3. The first organic element part EY1 may overlap the flat area PA and be disposed on the substrate SUB2. The second organic element part EY2 may overlap the first bending area BA1 and be disposed on the substrate SUB2. The third organic element part EY3 may overlap the second bending area BA2 and be disposed on the substrate SUB2.

According to an embodiment of the inventive concept, the first organic element part EY1 and the second organic element part EY2 may be separated by a first adhesive layer SLC1a. The first organic element part EY1 and the third organic element part EY3 may be separated by a second adhesive layer SLC2a.

The encapsulation layer EG may be disposed on the display element layer EY so as to seal the display element layer EY. Specifically, the encapsulation layer EG may include first to third encapsulation substrates EG1 to EG3.

The first encapsulation substrate EG1 may overlap the flat area PA and be disposed on the first organic element part EY1. The first encapsulation substrate EG1 seals the first organic element part EY1 in order to prevent external moisture or foreign matter from penetrating into the first organic element part EY1.

The second encapsulation substrate EG2 may be spaced apart from the first encapsulation substrate EG1 with the first adhesive layer SLC1a disposed therebetween, overlap the first bending area BA1, and be disposed on the second organic element part EY2. The second encapsulation substrate EG2 seals the second organic element part EY2 in order to prevent external moisture or foreign matter from penetrating into the second organic element part EY2.

The third encapsulation substrate EG3 may be spaced apart from the first encapsulation substrate EG1 with the second adhesive layer SLC2a disposed therebetween, overlap the second bending area BA2, and be disposed on the third organic element part EY3. The third encapsulation substrate EG3 seals the third organic element part EY3 in order to prevent external moisture or foreign matter from penetrating into the third organic element part EY3.

The polarization layer POL may cover the first and second adhesive layers SLC1a and SLC2a, and be disposed on the encapsulation layer EG.

As the first adhesive layer SLC1a and the second adhesive layer SLC2a illustrated in FIG. 5B include, like the adhesive layers illustrated in FIG. 4B, a flexible material such as silicone, a bending characteristic may result better than that of a substrate of a glass or plastic material.

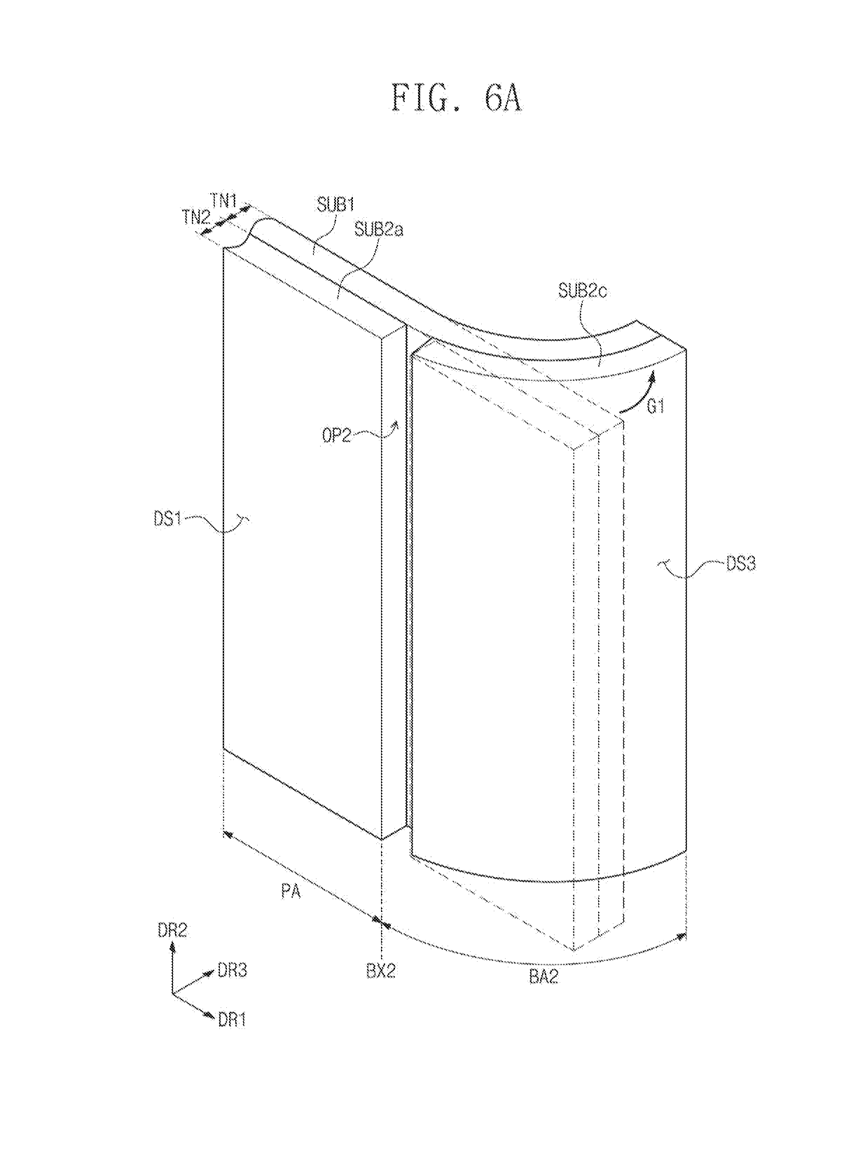

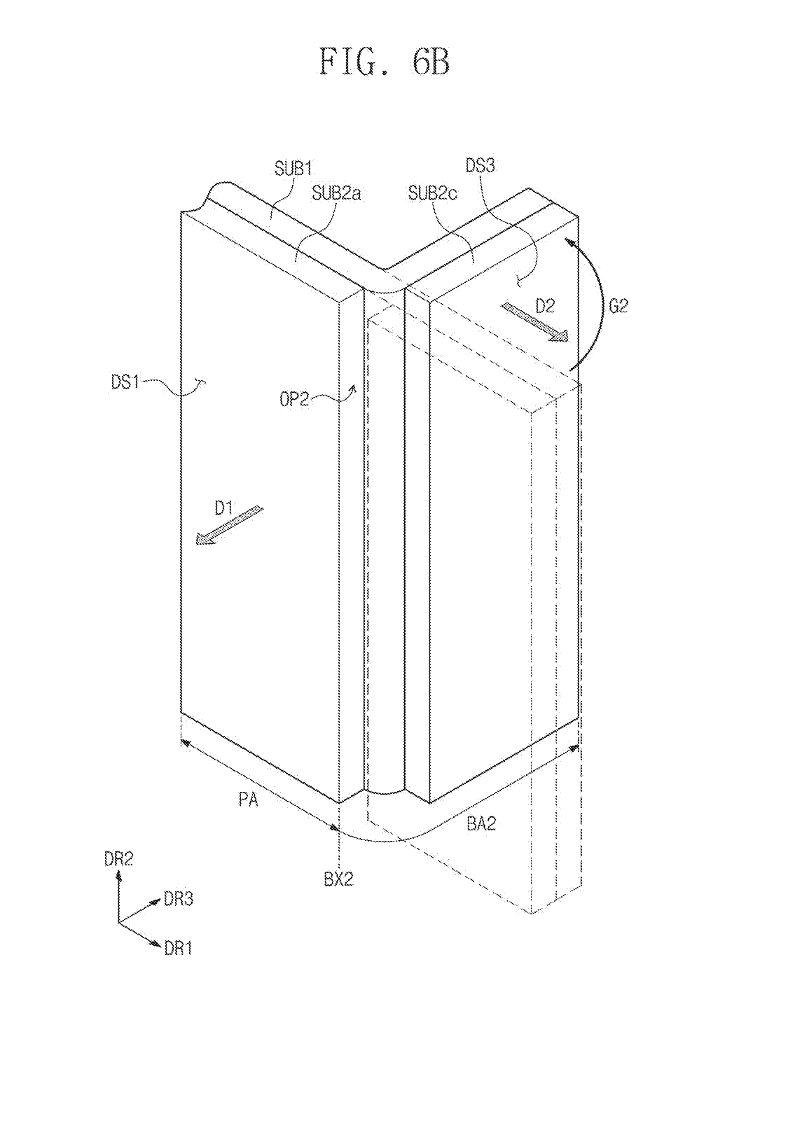

FIG. 6A is an enlarged view of an AA area illustrated in FIG. 2, according to an embodiment of the inventive concept. FIG. 6B is an enlarged view of the AA area illustrated in FIG. 2, according to another embodiment of the inventive concept.

Illustrated in FIG. 6A is only a configuration of the first substrate SUB1 and the second substrate SUB2, for convenience of description, among components of the display panel DP illustrated in FIG. 4B.

Referring to FIGS. 4B and 6A, the second bending area BA2 may be bent from the flat area PA. Specifically, the second bending part BA2 of the first substrate SUB1 may be bent from the flat part, and the third part SUB2c may be bent from the first part SUB2a.

According to an embodiment, the second bending part SUB2b and the third part SUB2c may be bent in a first bending direction G1. A first image displayed on the first display surface DS1 may be viewed by a user viewing a front surface of the display panel DP, but may be difficult to be viewed by a user viewing a side surface of the display panel DP. Accordingly, the display panel DP according to an embodiment of the inventive concept may also provide a third image displayed on the third display surface DS3 to a user viewing the side surface of the display panel DP.

Additionally, the second bending area BA2 according to an embodiment of the inventive concept may be more easily bent from the flat area PA due to the second space OP2. That is, as the third part SUB2c is spaced apart from the first part SUB2a with the second space OP2 disposed therebetween, only the first substrate SUB1 may be substantially bent in an area overlapping the second space OP2 of the second bending area BA2. Considering a bending characteristic becomes worse as a substrate becomes thicker, the second bending area BA2 according to an embodiment of the inventive concept may be more easily bent because only the thickness of the first substrate SUB1 is bent.

For example, the thickness of the first substrate SUB1 is defined as a first thickness TN1, and the thickness of the second substrate SUB2 is defined as a second thickness TN2. The first thickness TN1 and the second thickness TN2 may be equal or different from each other. In this case, the second bending area BA2 which is bent may only have the first thickness TN1 of the first substrate SUB1. Specifically, a better bending characteristic may be achieved when the substrate has the first thickness TN1 than when the substrate has a sum of the first and second thicknesses TN1 and TN2.

In addition, according to an embodiment of the inventive concept, the third part SUB2c may be bent with a curvature equal to that of the second bending part.

Referring to FIGS. 4B and 6B, the second bending part SUB2b and the third part SUB2c may be bent in a second bending direction G2. When compared with the second bending area BA2 illustrated in FIG. 6A, the second bending area BA2 illustrated in FIG. 6B may be bent more.

The third part SUB2c may be provided in a planar shape. Accordingly, the first part SUB2a may display a first image in a direction of a first axis D1, and the third part SUB2c may display a second image in a direction of a second axis D2 substantially perpendicular to the first axis D1. In this case, it becomes easier to view an image in a side surface of the display panel DPa.

FIGS. 7A to 7D illustrate a method of manufacturing a display device according to an embodiment of the inventive concept.

Referring to FIG. 7A, a first substrate SUB1 and a second substrate SUB2 disposed on the first substrate SUB1 are disposed. As an example, a liquid crystal layer or an organic element layer may be disposed between the first substrate SUB1 and the second substrate SUB2, as described in detail above. When disposing a second substrate SUB2 on the first substrate SUB1, the sealing layer SB which includes the first sealing layer SB1, the second sealing layer SB2 and the third sealing layer SB3 may be disposed between the first substrate SUB1 and the second substrate SUB2.

Referring to FIG. 7B, a first space OP1 and a second space OP2 are defined in the second substrate SUB2 to dispose, therein, a first adhesive layer SLC1 and a second adhesive layer SLC2 illustrated in FIG. 4B. In other words, a portion corresponding to the first space OP1 in which the first adhesive layer SLC1 is disposed is removed from the second substrate SUB2, and a portion corresponding to the second space OP2 in which the second adhesive layer SLC2 is disposed is removed from the second substrate SUB2. Here, the first and second spaces OP1 and OP2 may be formed by various methods such as laser, etching and a grinder.

As a result, the second substrate SUB2 may be separated into first to third parts SUB2a, SUB2b and SUB2c spaced apart from each other in a first direction DR1.

Referring to FIG. 7C, the first adhesive layer SLC1 is disposed in the first space OP1, and the second adhesive layer SLC2 is disposed in the second space OP2.

Referring to FIG. 7D, a first bending area BA1 may be bent from a flat area PA with the first adhesive layer SLC1 as a starting point. Additionally, a second bending area BA2 may be bent from the flat area PA with the second adhesive layer SLC2 as a starting point.

According to an embodiment of the inventive concept, the display panel includes the flat area for displaying a first image and the bending area that is bent from the flat area and displays a second image. In particular, as images are provided in directions crossing each other by the first display surface on which a first image is viewed and the second display surface on which a second image is viewed, the images may be viewed at various angles.

As described above, the embodiments are disclosed in the figures and specification. Although specific terms are employed herein, they are used only for purposes of describing the inventive concept and are not used to limit the scope of the inventive concept as defined in the claims. Accordingly, it is understood that various changes and modifications can be made by those skilled in the art. Therefore, the scope of the inventive concept is defined by the spirit of the following claims or the equivalents.

What is claimed is:

1. A display device comprising:
a first substrate including a flat part and a bending part bent from the flat part;
a second substrate facing the first substrate, and including a first part overlapping the flat part in a thickness direction of the first substrate and a second part that is spaced apart from the first part to expose a portion of the bending part and overlaps the bending part in the thickness direction;
a display element layer disposed between the first substrate and the second substrate; and
an adhesive layer disposed in a space between the first part and the second part spaced apart from each other, and configured to bond the first substrate and the second substrate.

2. The display device of claim 1, wherein the display element layer comprises:
a first liquid crystal part disposed between the flat part and the first part; and
a second liquid crystal part spaced apart from the first liquid crystal part and disposed between the bending part and the second part, and
wherein the adhesive layer is disposed between the first liquid crystal part and the second liquid crystal part.

3. The display device of claim 2, further comprising:
a first sealing layer disposed between the flat part and the first part so as to seal the first liquid crystal part; and
a second sealing layer disposed between the bending part and the second part so as to seal the second liquid crystal part.

4. The display device of claim 2, further comprising:
a first polarization layer disposed on the first substrate; and
a second polarization layer configured to cover the adhesive layer and disposed on the second substrate.

5. The display device of claim 2, further comprising:
a first color filter disposed on the first part; and
a second color filter spaced apart from the first color filter and disposed on the second part,
wherein the adhesive layer is disposed between the first color filter and the second color filter.

6. The display device of claim 1, wherein the bending part and the second part are bent in a direction from the second substrate to the first substrate.

7. The display device of claim 1, wherein the bending part and the second part are bent in a direction from the first substrate to the second substrate.

8. The display device of claim 1, wherein the bending part comprises a first bending part and a second bending part respectively bent from one end and the other end of the flat part.

9. The display device of claim 8, wherein the second part comprises:
a first sub-part spaced apart from one end of the first part, and configured to expose a portion of the first bending part and overlap the first bending part; and
a second sub-part spaced apart from the other end of the first part, and configured to expose a portion of the second bending part and overlap the second bending part.

10. The display device of claim 9, wherein the adhesive layer comprises:
a first adhesive layer disposed between the first part and the first sub-part; and
a second adhesive layer disposed between the first part and the second sub-part.

11. The display device of claim 1, wherein the second part is bent with a curvature equal to a curvature of the bending part.

12. The display device of claim 1, wherein the second part is flat.

13. The display device of claim 12, wherein a first image displayed from the first part and a second image displayed from the second part are respectively displayed in directions substantially perpendicular to each other.

14. The display device of claim 1, wherein the second substrate is provided as an encapsulation substrate.

15. The display device of claim 14, wherein the display element layer comprises:
a first organic element part disposed between the flat part and the first part; and
a second organic element part spaced apart from the first organic element part and disposed between the bending part and the second part, and
wherein the adhesive layer is disposed between the first organic element part and the second organic element part.

16. The display device of claim 15, further comprising a polarization layer configured to cover the adhesive layer and disposed on the second substrate.

17. A method of manufacturing a display device, the method comprising:
providing a first substrate including a flat part in which a plurality of first pixels are arranged, and a bending part which extends from the flat part and in which a plurality of second pixels are arranged;
disposing, on the first substrate, a second substrate including a first part overlapping the flat part and a second part extending from the first part to overlap the bending part, in a thickness direction of the first substrate;
removing a portion of the second part so that the second part is spaced apart from the first part;
disposing an adhesive layer for bonding the first substrate and the second substrate in the removed portion; and
bending the bending part and the second part.

18. The method of claim 17, wherein the bending part and the second part are bent in a direction from the second substrate to the first substrate.

19. The method of claim 17, wherein the adhesive layer is silicone.

20. The method of claim 17, wherein the first substrate and the second substrate are flexible.
